(19) United States
(12) Patent Application Publication
(10) Pub. No.: US 2025/0338527 A1
(43) Pub. Date: Oct. 30, 2025

(54) NANOSTRUCTURE PROFILE IN GAA AND THE METHODS OF FORMING THE SAME

(71) Applicant: Taiwan Semiconductor Manufacturing Co., Ltd., Hsinchu (TW)

(72) Inventors: Shun-Siang Jhan, Kaohsiung City (TW); Chien-Chia Cheng, Hsinchu (TW); Hung-Yao Chen, Hsinchu (TW); Chien-Hung Chen, Hsinchu (TW); Yi-Cheng Li, Yunlin County (TW); Ta-Chun Ma, New Taipei City (TW); Ming-Hua Yu, Hsinchu (TW); Chii-Horng Li, Zhubei City (TW)

(21) Appl. No.: 19/259,920

(22) Filed: Jul. 3, 2025

Related U.S. Application Data
(63) Continuation of application No. 18/680,682, filed on May 31, 2024.
(60) Provisional application No. 63/562,295, filed on Mar. 7, 2024.

(51) Int. Cl. H10D 30/01; H01L 21/02; H01L 21/306; H01L 21/3065; H10D 30/43; H10D 30/67; H10D 62/10; H10D 64/01

(52) U.S. Cl. CPC H10D 30/014; H01L 21/02057; H01L 21/30604; H01L 21/3065; H10D 30/43; H10D 30/6735; H10D 30/6757; H10D 62/121; H10D 64/017

(57) ABSTRACT

A method includes forming a multilayer stack, which includes a plurality of semiconductor layers and a plurality of sacrificial layers located alternatingly. The method further includes forming a dummy gate stack on the multilayer stack, etching the multilayer stack to form a trench, epitaxially growing a semiconductor region in the trench to form a source/drain region, and removing the plurality of sacrificial layers from the multilayer stack. After the sacrificial layers are removed, an etching process is performed. After the etching process, a gate stack is formed around the plurality of semiconductor layers.

### PRIORITY CLAIM AND CROSS-REFERENCE

This application is a continuation of U.S. patent application Ser. No. 18/680,682, filed on May 31, 2024, which application claims the benefit of the following provisionally filed U.S. Patent application: Application No. 63/562,295, filed on Mar. 7, 2024, and entitled “SILICON SHEET PROFILE IN GAAFET,” which applications are hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 10C, 11A, 11B, 12A, 12B, 13A, 13B, 14A, 14B, 15A, 15B, 16A, 16B, 16C, 17A, 17B, and 17C illustrate the views of intermediate stages in the formation of nanostructure transistors in accordance with some embodiments.

FIGS. 18-20, 21A, 21B, and 21C illustrate cross-sectional views of the removal of sacrificial layers and the formation of interfacial layers in accordance with some embodiments.

FIG. 22 illustrates a process flow for forming a nanostructure transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Gate All Around (GAA) transistor (also referred to as a nanostructure transistor) and the method of forming the same are provided in accordance with some embodiments. The formation of the GAA transistor includes forming a multilayer stack including semiconductor nanostructures and sacrificial layers, and forming a dummy gate stack on the multilayer stack. The dummy gate stack and the sacrificial layers are removed. An etching process may then be performed to remove the germanium intermix layers on the surfaces of the semiconductor nanostructures. The profile of the nanostructures is also shaped through the etching process.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

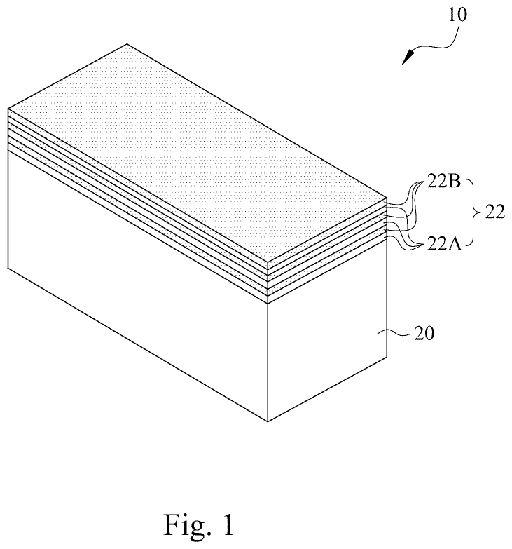

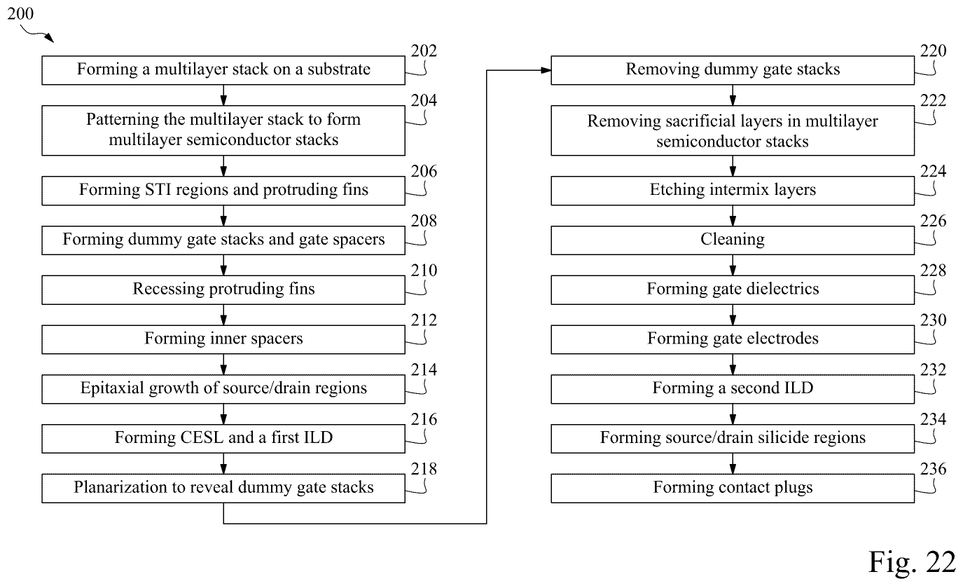

FIGS. 1-4, 5A, 5B, 6A, 6B, 7A, 7B, 8A, 8B, 9A, 9B, 10A, 10B, 10C, 11A, 11B, 12A, 12B, 13A, 13B, 14A, 14B, 15A, 15B, 16A, 16B, 16C, 17A, 17B, and 17C illustrate the views of intermediate stages in the formation of a nanostructure transistor in accordance with some embodiments of the present disclosure. The corresponding processes are also reflected schematically in the process flow as shown in FIG. 22.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 shown in FIG. 22. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. However, the second layer 22B may also be formed to a thickness that is different from the first layer 22A. In accordance with some embodiments, the second layer 22B may be formed to a second thickness in the range between about 10 Å and about 500 Å, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B in accordance with alternative embodiments. In accordance with some embodiments, first layers 22A are removed in the subsequent processes, and are alternatively referred to as sacrificial layers 22A throughout the description. In accordance with alternative embodiments, second layers 22B are removed in the subsequent processes.

In accordance with some embodiments, there are some pad oxide layer(s) and hard mask layer(s) (not shown) formed over multilayer stack 22, which layers are used for the patterning process as presented in subsequent figures. These layers are patterned, and are used for the subsequent patterning of multilayer stack 22.

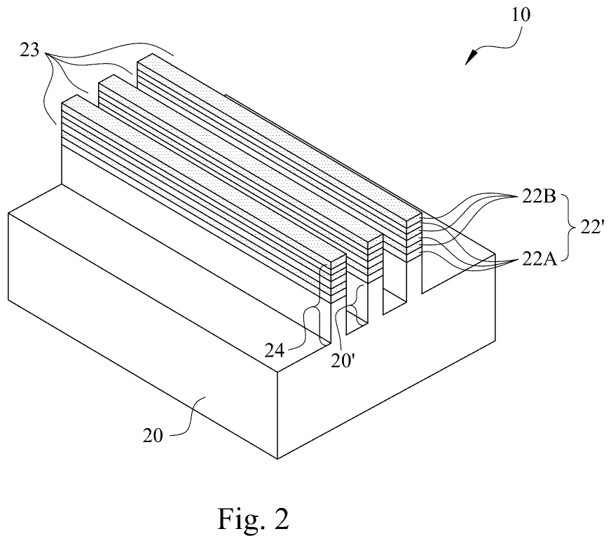

Referring to FIG. 2, multilayer stack 22 and a portion of the underlying substrate 20 are patterned in an etching process(es), so that trenches 23 are formed. The respective process is illustrated as process 204 in the process flow 200 shown in FIG. 22. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

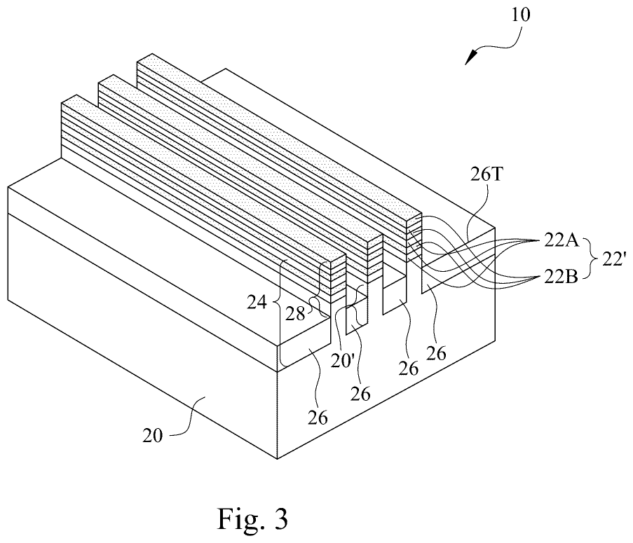

FIG. 3 illustrates the formation of isolation regions 26, which are also referred to as Shallow Trench Isolation (STI) regions throughout the description. The respective process is illustrated as process 206 in the process flow 200 shown in FIG. 22. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

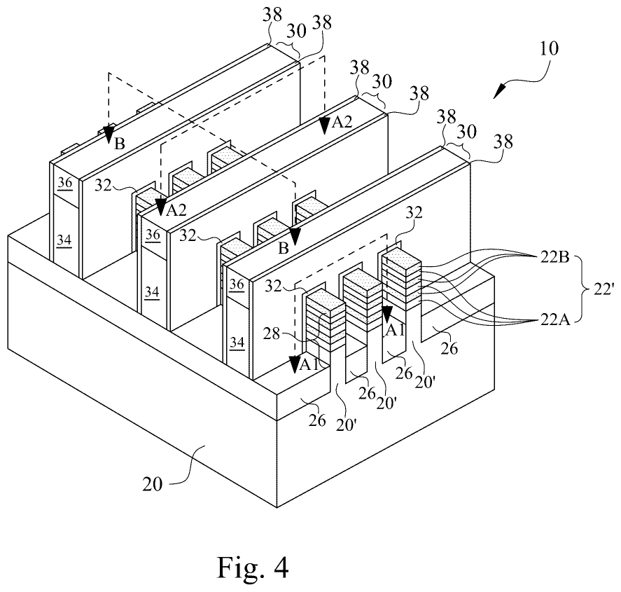

Referring to FIG. 4, dummy gate stacks 30 and gate spacers 38 are formed on the top surfaces and the sidewalls of (protruding) fins 28. The respective process is illustrated as process 208 in the process flow 200 shown in FIG. 22. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers. Dummy gate electrodes 34 may be formed, for example, using polysilicon or amorphous silicon, and other materials such as amorphous carbon may also be used. Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof.

The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

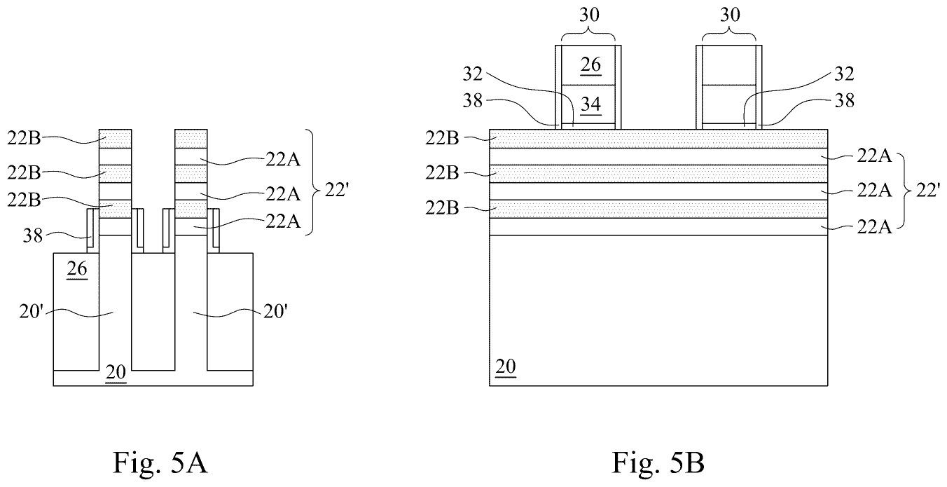

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by gate stacks 30 and gate spacers 38, and is parallel to the gate-length direction. FIG. 5B illustrates the reference cross-section B-B in FIG. 4, which reference cross-section is parallel to the lengthwise directions of protruding fins 28.

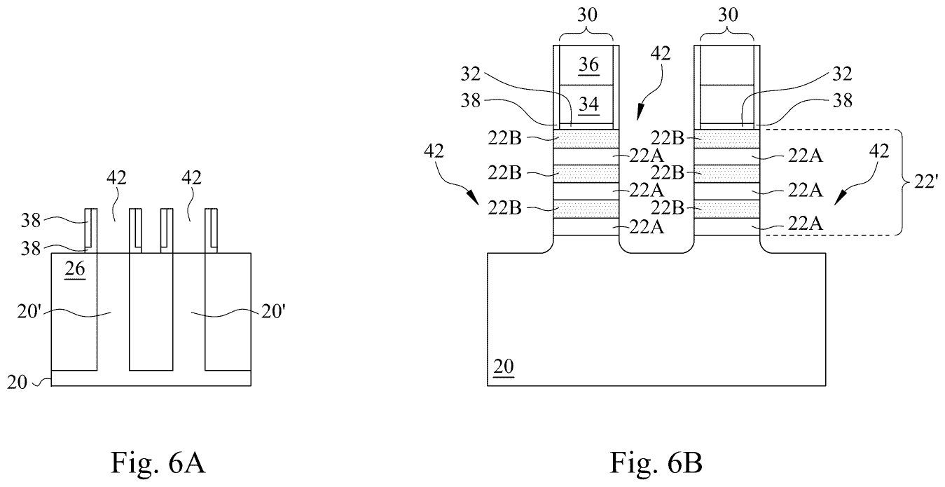

Referring to FIGS. 6A and 6B, the portions of protruding fins 28 that are not directly underlying dummy gate stacks 30 and gate spacers 38 are recessed through an etching process to form recesses 42. The respective process is illustrated as process 210 in the process flow 200 shown in FIG. 22. For example, a dry etch process may be performed using tetramethylammonium hydroxide (TMAH) or the like to etch multilayer stacks 22′ and the underlying substrate strips 20′. The bottoms of recesses 42 are at least level with, or may be lower than (as shown in FIG. 6B), the bottoms of multilayer stacks 22′. The etching may be anisotropic, so that the sidewalls of multilayer stacks 22′ facing recesses 42 are vertical and straight, as shown in FIG. 6B.

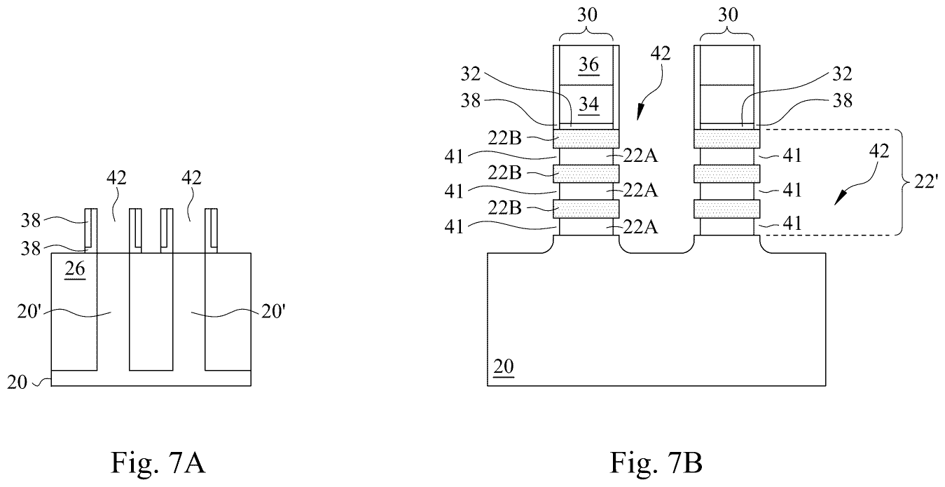

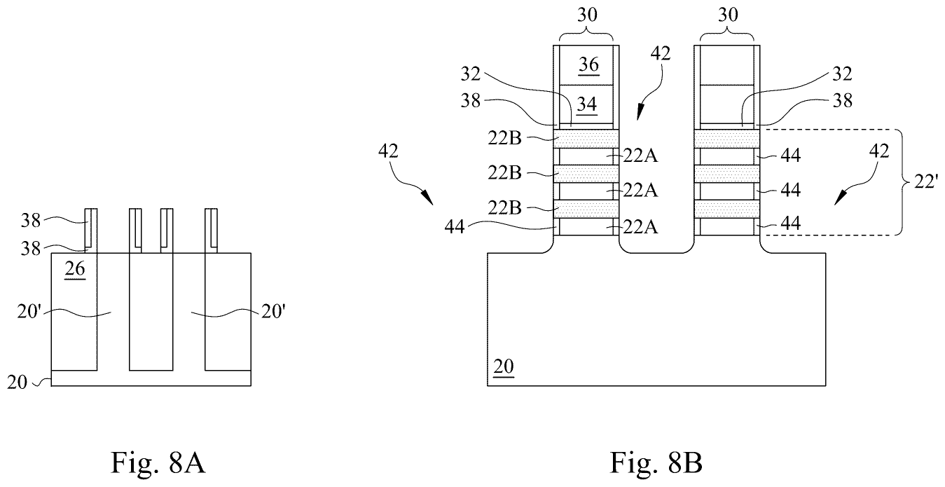

Referring to FIGS. 7A and 7B and FIGS. 8A and 8B, inner spacers 44 are formed. The respective process is illustrated as process 212 in the process flow 200 shown in FIG. 22. In accordance with some embodiments, the formation of inner spacers 44 may include laterally recessing sacrificial semiconductor layers 22A to form recesses 41, as shown in FIGS. 7A and 7B.

Once sacrificial semiconductor layers 22A are recessed laterally to form the recesses 41, a spacer material is deposited to fill the corresponding recesses. The spacer material may be different from the material of gate spacers 38, and may be a dielectric material comprising silicon such as silicon oxycarbonitride (SiOCN), silicon nitride (SiN), silicon oxide (SiO₂), silicon oxynitride (SiON), silicon carbo-nitride (SiCN), silicon oxycarbide (SiOC), or the like, while any other suitable material such as low-k materials with a k-value less than about 3.5, or combination thereof may also be utilized. The spacer material may be deposited using a conformal deposition process such as CVD, ALD, or the like, to a thickness in the range between about 2 nm and about 10 nm, for example.

A dry etching and/or a wet etching process is then performed to remove the portions of the spacer material on the sidewalls of nanostructures 22B, so that the sidewalls of nanostructures 22B are exposed. The remaining portions of the spacer material are inner spacers 44, as shown in FIGS. 8A and 8B. Inner spacers 44 are used to isolate the subsequently formed gate structures from the subsequently formed source/drain regions, and to prevent the damage of the source/drain regions in subsequent etching processes, such as the etching of dummy gate stacks 30.

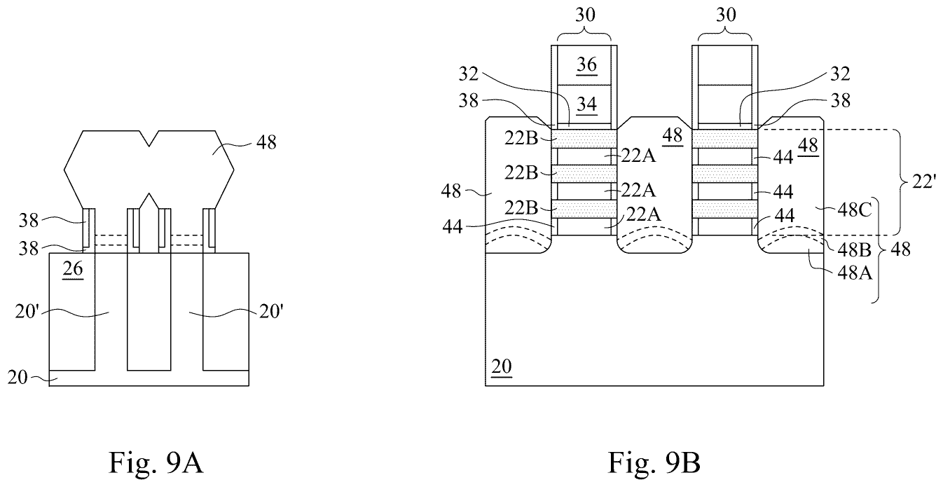

Referring to FIGS. 9A and 9B, epitaxial source/drain regions 48 are formed in recesses 42. The respective process is illustrated as process 214 in the process flow 200 shown in FIG. 22. In accordance with some embodiments, the source/drain regions 48 may exert stress on the nanostructures 22B, which are used as the channels of the corresponding GAA transistors, thereby improving performance. Depending on whether the resulting transistor is a p-type transistor or an n-type transistor, a p-type or an n-type impurity may be in-situ doped with the proceeding of the epitaxy. For example, when the resulting transistor is a p-type Transistor, silicon germanium boron (SiGeB), silicon boron (SiB), or the like may be grown.

Conversely, when the resulting transistor is an n-type Transistor, silicon phosphorous (SiP), silicon carbon phosphorous (SiCP), or the like may be grown. After recesses 42 are filled with epitaxial source/drain regions 48, the further epitaxial growth of epitaxial source/drain regions 48 causes epitaxial source/drain regions 48 to expand horizontally, and facets may be formed. The further growth of epitaxial source/drain regions 48 may also cause neighboring epitaxial source/drain regions 48 to merge with each other.

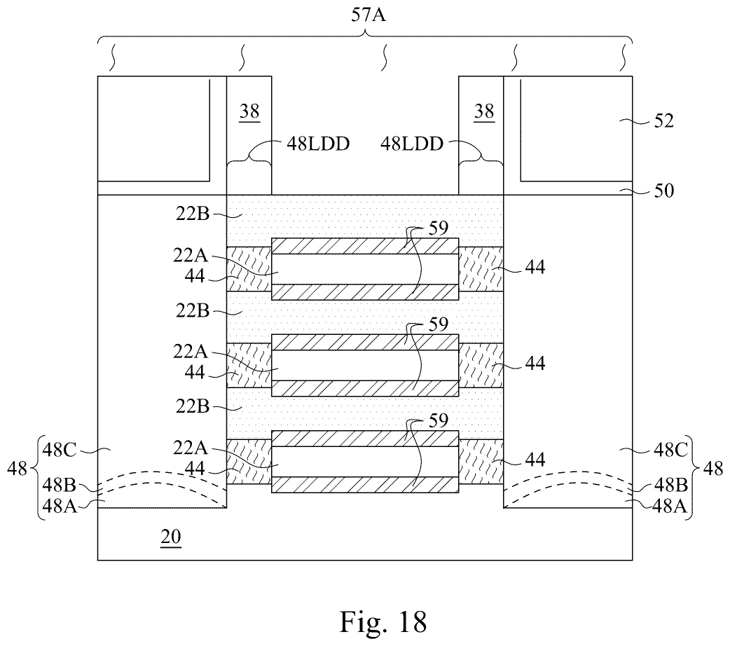

Epitaxial source/drain regions 48 may include a plurality of sub layers. For example, FIGS. 9A and 9B (and also FIG. 18) illustrate that source/drain regions 48 include a plurality of subs layers 48A (also referred to as L0), 48B (L1), and 48C(L2) as an example. The sub layers may have different compositions such as different dopant concentrations, and/or different atomic percentages of Si, Ge, C, or the like. In subsequent figures, the sub layers may not be illustrated, while they may still exist.

After the epitaxy process, epitaxial source/drain regions 48 may be further implanted with a p-type or an n-type impurity to form source and drain regions, which are also denoted using reference numeral 48. In accordance with alternative embodiments of the present disclosure, the implantation process is skipped when epitaxial source/drain regions 48 are in-situ doped with the p-type or n-type impurity during the epitaxy.

In accordance with some embodiments, the dopant in epitaxial source/drain regions 48 may diffuse into the portions of the nanostructures 22B overlapped by gate spacers 38 to form Lightly-doped Source/Drain (LDD) regions 48LDD, which are illustrated in FIG. 18. LDD regions 48LDD may also be formed, for example, during the process shown in FIG. 6B by performing tilt implantation process to introduce a p-type or n-type dopant into the portions of nanostructures 22B overlapped by gate spacers 38.

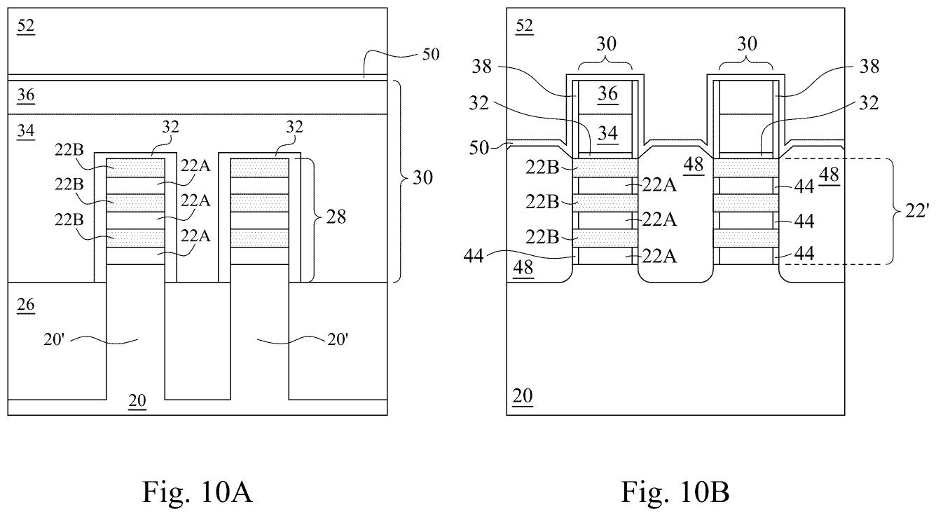

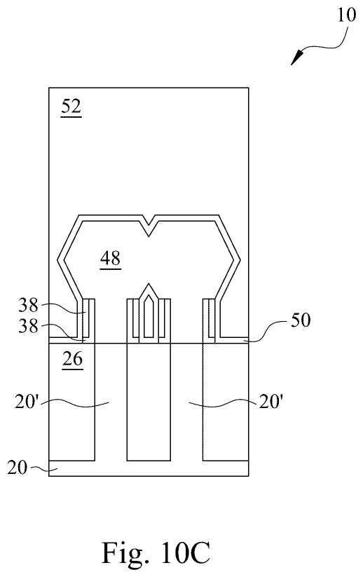

The subsequent figure numbers in FIGS. 10A, 10B, and 10C through FIGS. 17A, 17B, and 17C may have numbers followed by letter A, B, or C, wherein the figures with the figure numbers having the letter A indicates that the corresponding figures show the reference cross-sections same as the reference cross-section A2-A2 in FIG. 4, the figures with the figure numbers having the letter B indicate that the corresponding figures show the reference cross-sections same as the reference cross-section B-B in FIG. 4, and the figures with the figure numbers having the letter C indicate that the corresponding figures show the reference cross-sections same as the reference cross-section A1-A1 in FIG. 4.

FIGS. 10A, 10B, and 10C illustrate the cross-sectional views of the structure after the formation of Contact Etch Stop Layer (CESL) 50 and Inter-Layer Dielectric (ILD) 52. The respective process is illustrated as process 216 in the process flow 200 shown in FIG. 22. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be a silicon oxide, Phospho-Silicate Glass (PSG), Boro-Silicate Glass (BSG), Boron-Doped Phospho-Silicate Glass (BPSG), Undoped Silicate Glass (USG), or the like.

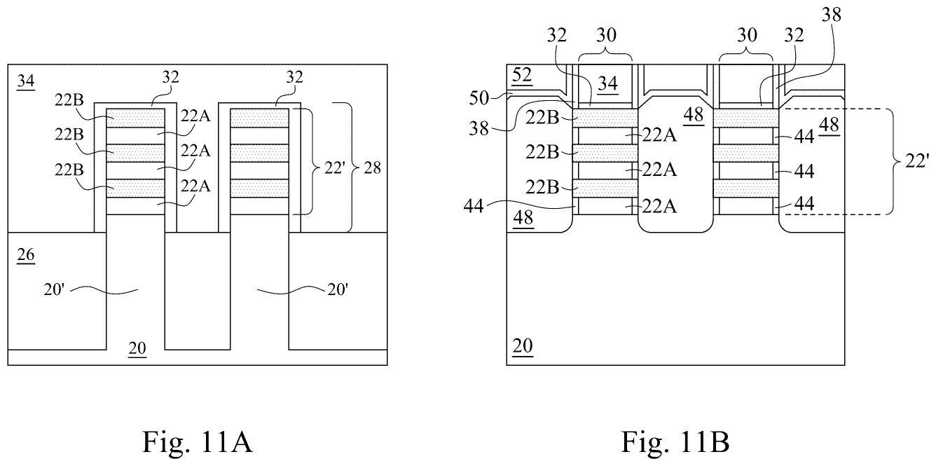

FIGS. 11A and 11B through FIGS. 15A and 15B illustrate the process for forming replacement gate stacks. In FIGS. 11A and 11B, a planarization process such as a CMP process or a mechanical grinding process is performed to level the top surface of ILD 52. The respective process is illustrated as process 218 in the process flow 200 shown in FIG. 22. In accordance with some embodiments, the planarization process may remove hard masks 36 to reveal dummy gate electrodes 34. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

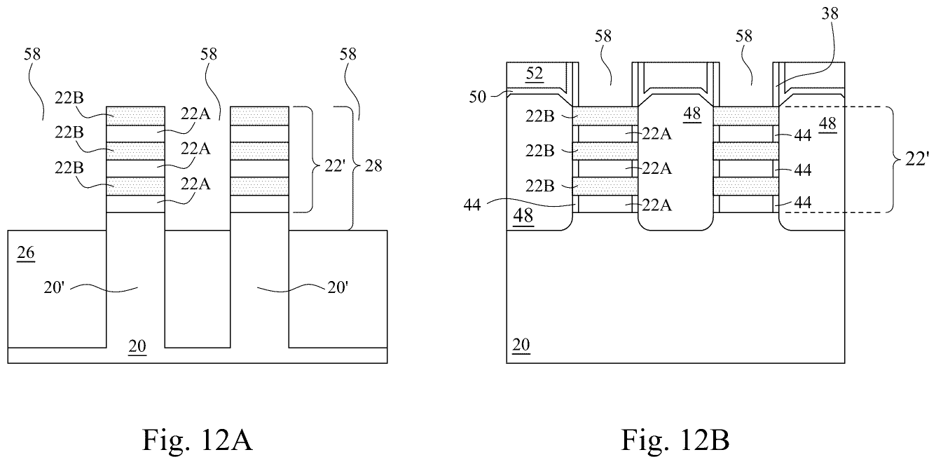

Next, dummy gate electrodes 34 (and hard masks 36, if remaining) are removed in one or more etching processes, so that recesses 58 are formed, as shown in FIGS. 12A and 12B. The respective process is illustrated as process 220 in the process flow 200 shown in FIG. 22. The portions of the dummy gate dielectrics 32 in recesses 58 are also removed. In accordance with some embodiments, dummy gate electrodes 34 and dummy gate dielectrics 32 are removed through an anisotropic dry etch process. For example, the etching process may be performed using reaction gas(es) that selectively etch dummy gate electrodes 34 at a faster rate than ILD 52. Each recess 58 exposes and/or overlies portions of multilayer stacks 22′, which include the future channel regions in subsequently completed nano-FETs. The portions of the multilayer stacks 22′, which act as the channel regions, are between neighboring pairs of the epitaxial source/drain regions 48.

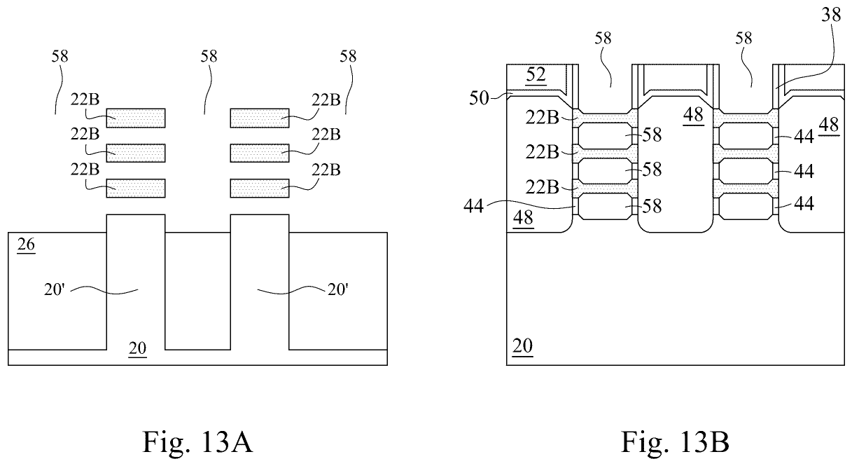

Recesses 58 are then extended downwardly between nanostructures 22B, and the resulting structure is shown in FIGS. 13A and 13B. The detailed processes for forming the structure as shown in FIGS. 13A and 13B are illustrated in FIGS. 18 through 20, in which magnified views are provided.

Referring to FIG. 18, a portion of the structure in FIG. 13B is illustrated, in which the dummy gate stack has been removed, and the top one of nanostructures 22B has been exposed. The sidewalls of the multilayer stacks 22′ are exposed to recesses 58, as may be realized from FIG. 12A.

In accordance with some embodiments, intermix layers 59 are formed between nanostructures 22B and sacrificial layers 22A due to inter-diffusion. In accordance with some embodiments in which sacrificial layers 22A comprise silicon germanium and nanostructures 22B comprise silicon, intermix layers 59 may also include silicon germanium with lower germanium atomic percentages than in sacrificial layers 22A. Also, the portions of intermix layers 59 closer to sacrificial layers 22A have higher germanium atomic percentages than the respective portions of intermix layers 59 closer to nanostructures 22B. Intermix layers 59 may extend into both of sacrificial layers 22A and the nanostructures 22B. The portions of intermix layers 59 in sacrificial layers 22A have higher germanium atomic percentages than the portions of intermix layers 59 in the nanostructures 22B.

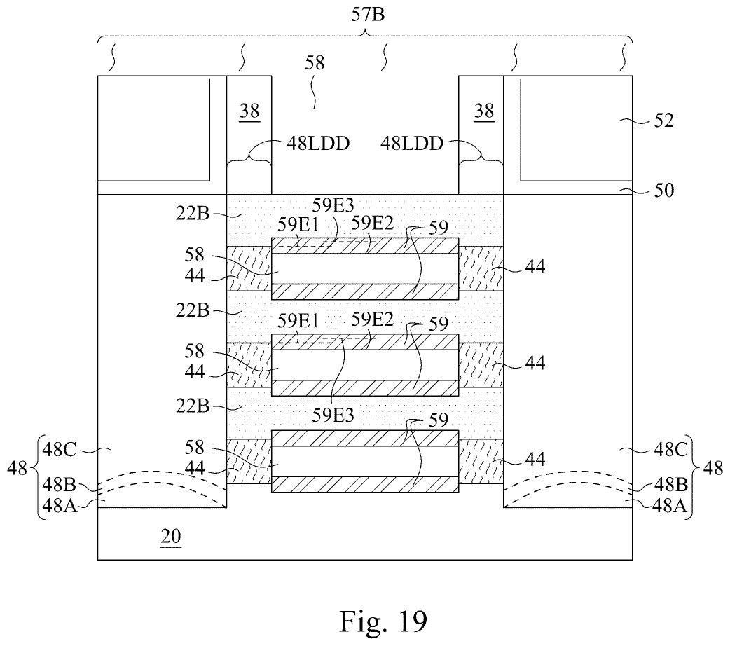

Next, sacrificial layers 22A are removed from sides (refer to FIGS. 12A and 13A) by performing an isotropic etching process 57A (FIG. 18) using etchants that are selective to the materials of sacrificial layers 22A. Recesses 58 thus extend to the regions between nanostructures 22B. The nanostructures 22B, substrate 20, and STI regions 26 remain relatively un-etched as compared to sacrificial layers 22A. The resulting structure is shown in FIG. 19. The respective process is illustrated as process 222 in the process flow 200 shown in FIG. 22. In accordance with some embodiments, etching process 57A comprises a dry etching process, for example, using process gases such as fluorine (F₂), Chlorine (Cl₂), hydrogen chloride (HCl), hydrogen bromide (HBr), Bromine (Br₂), C₂F₆, CF₄, SO₂, the mixture of HBr, Cl₂, and O₂, or the mixture of HBr, Cl₂, O₂, and CH₂F₂ etc. In accordance with alternative embodiments, a wet etching process is performed using a chemical solution such as tetra methyl ammonium hydroxide (TMAH), ammonium hydroxide (NH₄OH), or the like.

Due to the different composition (such as higher germanium atomic percentages) of sacrificial layers 22A than the intermix layers 59, after the etching of sacrificial layers 22A, at least some portions of intermix layers 59 close to nanostructures 22B are left. Depending on the etching duration, the exposed edges of the remaining intermix layers 59 may be at the positions shown as 59E1, 59E2, or 59E3. When the edges of the remaining intermix layers 59 are at positions 59E1, the upper or lower edges of the remaining intermix layers 59 are coplanar with the interfaces between LDD regions 48LDD and inner spacers 44. When the edges of the remaining intermix layers 59 are at positions 59E2 or 59E3, the remaining intermix layers 59 may protrude beyond, or recessed back from, the interfaces between LDD regions 48LDD and inner spacers 44.

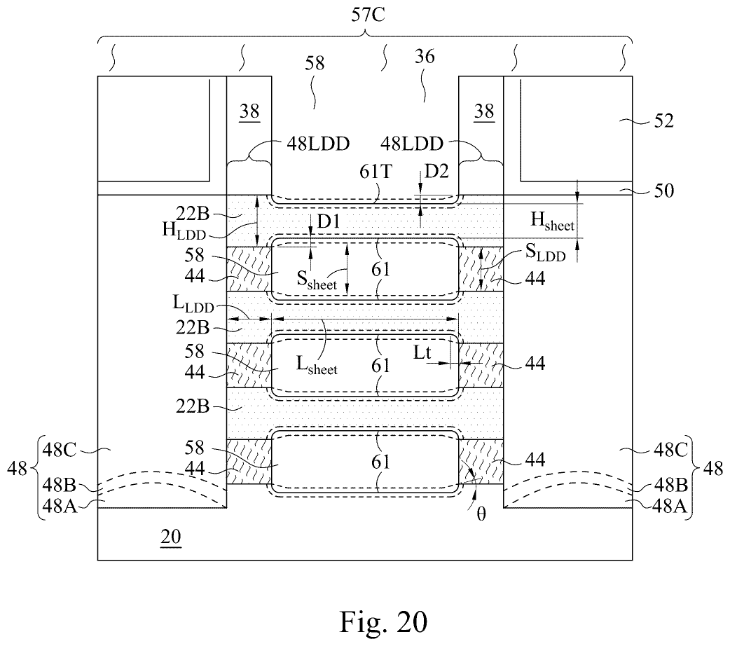

Next, referring to FIG. 19, an etching process 57B is performed to remove intermix layers 59. The respective process is illustrated as process 224 in the process flow 200 shown in FIG. 22. The resulting structure is shown in FIG. 20. The etching process 57B may be performed by using an etching chemical that is different from the etching chemical used in the removal of sacrificial layers 22A. The etching chemical may also etch germanium faster than etching silicon.

In accordance with some embodiments, the etching process 57B includes a wet etching process, and the etching chemical may comprise a solution of the mixture of ammonium hydroxide (NH₄OH), hydrogen peroxide (H₂O₂), and H₂O. The etching may be performed in open air, and at a temperature range between about 10° C. and about 90° C. The elevated temperature (higher than room temperature, which may be about 21° C.) may improve the efficiency of the etching. The etching time may be in the range between about 100 seconds and about 1,000 seconds.

As a result of the etching process 58B, recesses 61 and 61T are formed to extend into nanostructures 22B, and nanostructures 22B are thinned. For example, the portions of nanostructures 22B forming LDD regions 48LDD may have height H_{LDD}, and the recessed portions of nanostructures 22B may have height Hₛₕₑₑₜ that is smaller than height H_{LDD}. The difference (H_{LDD}−Hₛₕₑₑₜ) may be in the range between about 1 nm and about 4 nm. In accordance with some embodiments, the height Hₛₕₑₑₜ may be in the range between about 2 nm and about 8 nm, and may be in the range between about 3 nm and about 7 nm. The inter-sheet spacing Sₛₕₑₑₜ may be in the range between about 4 nm and about 12 nm, and may be in the range between about 6 nm and about 10 nm.

The height H_{LDD} may be in the range between about 3 nm and about 10 nm, and may be in the range between about 5 nm and about 9 nm. The inter-sheet spacing S_{LDD} may be in the range between about 2 nm and about 13 nm, and may be in the range between about 4 nm and about 8 nm. The length Lₛₕₑₑₜ of the sheet portion of nanostructures 22B may be in the range between about 5 nm and about 30 nm, and may be in the range between about 12 nm and about 24 nm. The length L_{LDD} of the LDD portion of nanostructures 22B may be in the range between about 2 nm and about 8 nm, and may be in the range 3 nm and about 7 nm.

In accordance with some embodiments, the sheet portions of nanostructures 22B have transition portions connecting the LDD regions 48LDD to the middle sheet portions that have the height Hₛₕₑₑₜ. The transition portions have gradually reduced heights, while the middle portions have a uniform height Hₛₕₑₑₜ. The recessing depth D1 of the recesses 61 may be greater than 0 nm and smaller than about 6 nm, such as in the range between about 1 nm and about 6 nm. A ratio D1/Hₛₕₑₑₜ, which is the ratio of the recessing depth D1 to the height Hₛₕₑₑₜ may be greater than about 0.05 or greater than about 0.1, and may be in the range between about 0.05 and about 0.2 or between about 0.1 and about 0.2, while smaller or higher values may be adopted. Different recesses 61 may also have the same depths D1, for example, with variations smaller than about 10 percent. The length Lt of the transition portion of the nanostructures 22B may also be greater than 0 nm and smaller than about 6 nm, such as in the range between about 1 nm and about 6 nm.

Due to the etching process 57B for removing intermixing layers 59, the top surface of the topmost nanostructure 22B may also be recessed to form recess 61T. In accordance with some embodiments, since no intermix layer is formed at the top surface of the topmost nanostructure 22B, and also due to that the etching rate of silicon is lower than the etching rate of germanium and silicon germanium during etching process 57B, the recessing depth D2 of recess 61T is smaller than the depths D1 of the underlying recesses 61. In accordance with some embodiments, ratio D2/D1 is smaller than about 2/3, and may be smaller than about 1/2, while the recessing depths of all underlying recesses 61 may be equal to or substantially equal to each other, for example, with less than about 10 percent variation.

The exposed surfaces of nanostructures 22B may have various profiles. For example, the illustrated surfaces of the transition portions of nanostructures 22B have curved surfaces. Alternatively, as shown by dashed lines, the surfaces of the transition portions of nanostructures 22B may be straight and slanted. The tilt angles θ may be smaller than about 60°, and may be in the range between about 15° and about 45°.

In accordance with alternative embodiments, due to process variations, recesses 61 may extend horizontally to form undercuts that are overlapped by the edge portions of gate spacers 38 and inner spacers 44. Accordingly, the top surfaces and bottom surfaces of inner spacers 44 and gate spacers 38 may be exposed to the edge portions of the overlaying and underlying recesses 61 and/or 61T.

Referring to FIG. 20, after the etching process 57B, a cleaning process 57C may be performed using a chemical that is different from the etching chemical used in the etching process 57B. The respective process is illustrated as process 226 in the process flow 200 shown in FIG. 22. In accordance with some embodiments, the cleaning process may be performed through a dry etching process using the mixture of HF gas and NH₃ gas. Accordingly, any oxide formed on nanostructures 22B and other residues such as nitrogen-containing chemicals and fluorine-containing chemicals are removed. The cleaning process 57C may be performed ex situ with the etching process 57B, for example, with the etching process 57B performed in open air, and the etching process 57B performed in a vacuum chamber. In addition, the cleaning process 57C may be performed and the subsequent formation of gate dielectrics may be in-situ performed in a same vacuum environment without vacuum break in between.

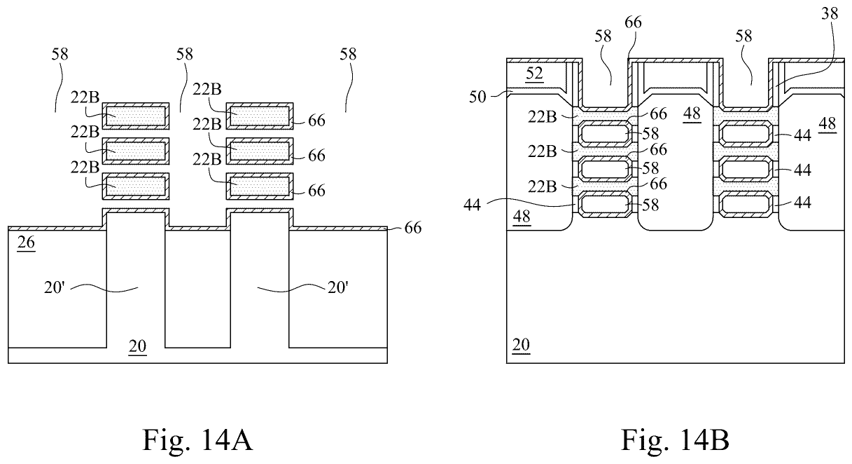

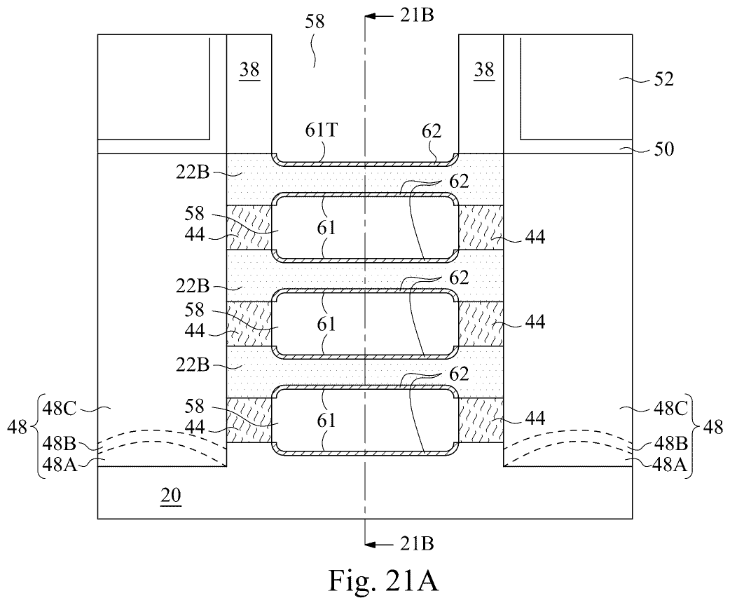

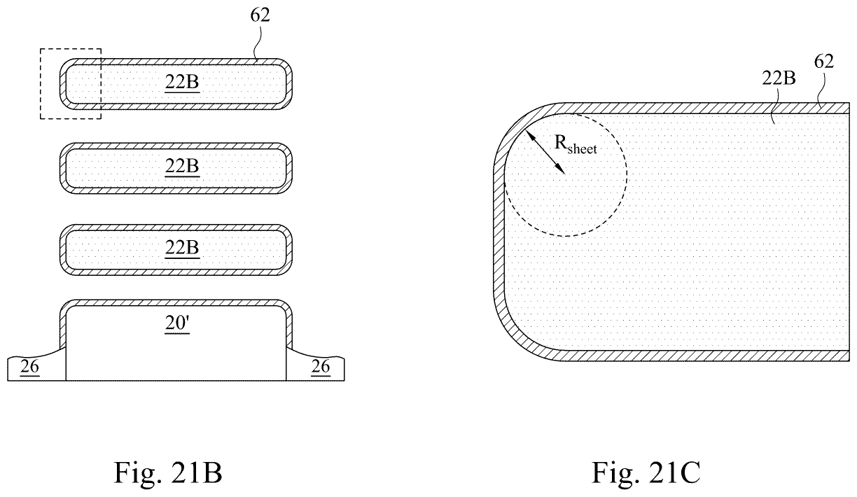

After the cleaning process 57C, as shown in FIGS. 14A and 14B, gate dielectrics 66 are formed. The respective process is illustrated as process 228 in the process flow 200 shown in FIG. 22. Gate dielectrics 66 may include interfacial layers (ILs) and high-k dielectric layers over the ILs. FIG. 21A illustrates the formation of interfacial layers 62, which may be formed of or comprise silicon oxide, and are also referred to as oxide layers 62. If undercuts (FIG. 20) are formed, gate dielectrics 66 (and possibly gate electrodes) also extend into the undercuts.

The formation of interfacial layers 62 may include a thermal oxidation process, a chemical oxidation process, a deposition process, or the like. When the deposition process is performed, ILs 62 also extend on the surfaces of dielectric materials. The illustrated ILs 62 shown in FIG. 21A have the profiles formed through the oxidation of nanostructures 22B.

FIG. 21B illustrates the cross-section 21B-21B as shown in FIG. 21A, in which ILs 62 are formed as encircling nanostructures 22B. Due to the etching process 57B, the corners of nanostructures 22B are rounded. For example, FIG. 21C illustrates a magnified view of a portion of the structure shown in FIG. 21B. In accordance with some embodiments, the curvature 1/Rₛₕₑₑₜ of the corners of nanostructures 22B may be smaller than about 2 nm⁻¹, which means that the corners may fit a circle with radius Rₛₕₑₑₜ, and radius Rₛₕₑₑₜ may be greater than about 2 nm.

Referring back to FIGS. 14A and 14B, the illustrated gate dielectrics 66 include the ILs 62 as shown in FIG. 21A and high-k dielectric layers (not shown separately) on ILs 62. The high-k dielectric layers are deposited conformally in recesses 58, with different portions of the high-k dielectric layers having a uniform thickness. The high-k dielectric layers may also be deposited on the top surfaces of the ILD 52, CESL 50, gate spacers 38, and STI regions 26. In accordance with some embodiments, the high-k dielectric layers are formed through a conformal deposition method such as ALD, CVD, or the like, so that the horizontal portions, the vertical portions, and the corner portions have the same thickness.

In accordance with some embodiments, the high-k dielectric layers comprise one or more dielectric layers, such as one or more metal oxide layers. For example, in accordance with some embodiments, the high-k dielectric layers may be formed of or comprise a high-k dielectric material, which may have a k value greater than about 7.0, and may include a metal oxide or a silicate of hafnium, aluminum, zirconium, lanthanum, manganese, barium, titanium, lead, and combinations thereof.

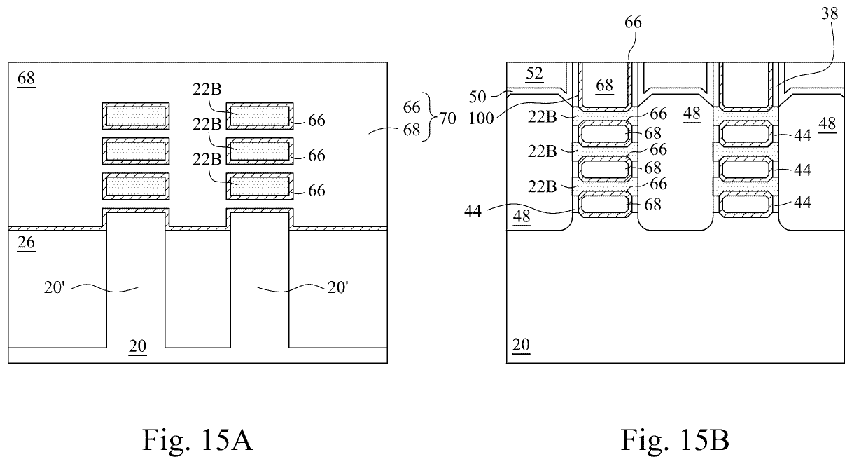

Referring to FIGS. 15A and 15B, gate electrodes 68 are deposited over the high-k dielectric layers. The respective process is illustrated as process 230 in the process flow 200 shown in FIG. 22. Gate electrodes 68 may include a metal-containing material such as TiN, TaN, TiAl, TiAlC, cobalt, ruthenium, aluminum, tungsten, combinations thereof, and/or multilayers thereof. For example, although single-layer gate electrodes 68 are illustrated, gate electrodes 68 may comprise any number of layers, any number of work function layers, and a filling material. Gate electrodes 68 may be deposited to fill the spaces between adjacent ones of nanostructures 22B, and fill the spaces between the bottom ones of nanostructures 22B and the underlying substrate strips 20′.

After the filling of recesses 58, a planarization process such as a CMP process or a mechanical grinding process is performed to remove the excess portions of the high-k dielectric layers and the material of gate electrodes 68, which excess portions are over the top surface of ILD 52. Gate electrodes 68 and gate dielectrics 66 (including oxide layers 62 and the high-k dielectric layers) are collectively referred to as gate stacks 70 of the resulting nano-FETs.

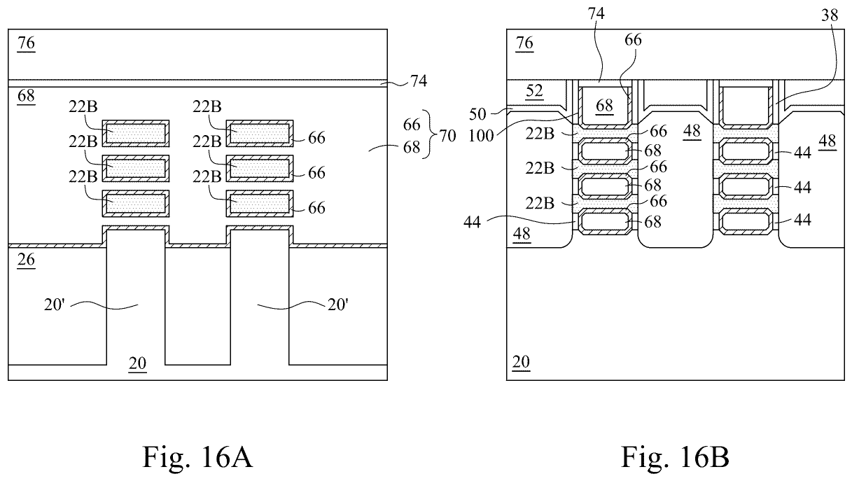

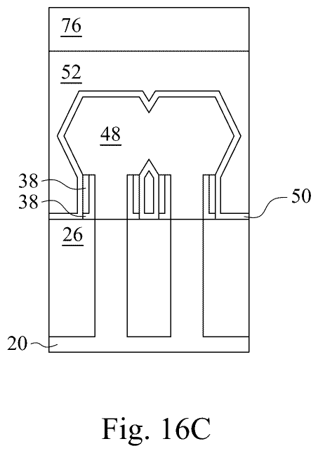

In the processes shown in FIGS. 16A, 16B, and 16C, gate stacks 70 (including the high-k dielectric layers and the corresponding overlying gate electrodes 68) are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52.

As further illustrated by FIGS. 16A, 16B, and 16C, ILD 76 is deposited over ILD 52 and over gate masks 74. The respective process is illustrated as process 232 in the process flow 200 shown in FIG. 22. An etch stop layer (not shown), may be, or may not be deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

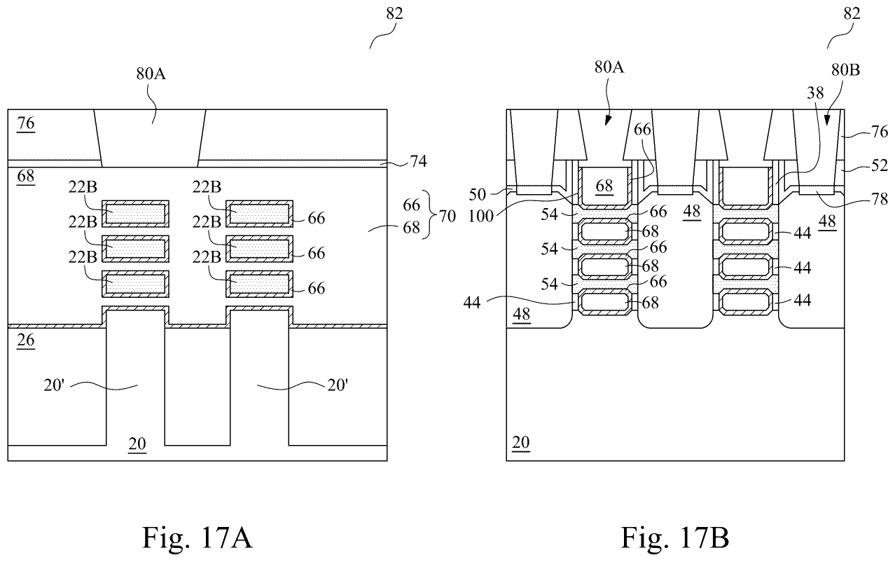

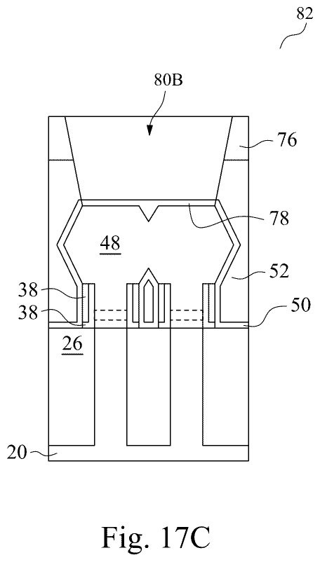

In FIGS. 17A, 17B, and 17C, ILD 76, ILD 52, CESL 50, and gate masks 74 are etched to form recesses (occupied by contact plugs 80A and 80B) exposing surfaces of the epitaxial source/drain regions 48 and/or gate stacks 70. The recesses may be formed through etching using an anisotropic etching process, such as RIE, NBE, or the like. In accordance with some embodiments, the recesses may be formed by etching-through ILD 76 and ILD 52 using a first etching process, etching-through gate masks 74 using a second etching process, and etching-through CESL 50 possibly using a third etching process. Although contact plugs 80A and 80B are shown as in a same cross-section, in various embodiments, contact plugs 80A and 80B may be formed in different cross-sections, thereby reducing the risk of shorting with each other.

After the recesses are formed, silicide regions 78 are formed over the epitaxial source/drain regions 48. The respective process is illustrated as process 234 in the process flow 200 shown in FIG. 22. In accordance with some embodiments, silicide regions 78 are formed by first depositing a metal layer (not shown) capable of reacting with the semiconductor materials of the underlying epitaxial source/drain regions 48 (for example, silicon, silicon germanium, germanium) to form silicide and/or germanide regions, then performing a thermal anneal process to form silicide regions 78. The metal may include nickel, cobalt, titanium, tantalum, platinum, tungsten, or the like. The un-reacted portions of the deposited metal are then removed, for example, by an etching process.

Contact plugs 80B are then formed over silicide regions 78. Also, contact plugs 80A (may also be referred to as gate contact plugs) are also formed in the recesses, and are over and contacting gate electrodes 68. The respective processes are illustrated as process 236 in the process flow 200 shown in FIG. 22. Contact plugs 80A and 80B may each comprise one or more layers, such as a barrier layer, a diffusion layer, and a fill material. For example, in accordance with some embodiments, contact plugs 80A and 80B each includes a barrier layer and a conductive material, and are electrically coupled to the underlying conductive feature (for example, gate stacks 70 and/or silicide region 78 in the illustrated embodiment). The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP process, may be performed to remove excess material from a surface of ILD 76. Nano-FET 82 is thus formed.

The embodiments of the present disclosure have some advantageous features. By etching the intermixing layer, the possible degradation to the resulting transistor is avoided. Also, by adjusting the etching process for etching the intermixing layer, the profiles of the nanosheets (channels) are shaped, so that the widths of the nanosheets reduce gradually from the LDD regions to the narrowed nanosheets. Current crowding effect is thus reduced. Drain Induced Barrier Lowering (DIBL) effect is reduced due to the reduction of the height of the silicon nanosheets.

In accordance with some embodiments of the present disclosure, a method comprises forming a multilayer stack comprising a plurality of semiconductor layers and a plurality of sacrificial layers located alternatingly; forming a dummy gate stack on the multilayer stack; etching the multilayer stack to form a trench; epitaxially growing a semiconductor region in the trench to form a source/drain region; removing the plurality of sacrificial layers from the multilayer stack; after the sacrificial layers are removed, performing an etching process; and after the etching process, forming a gate stack around the plurality of semiconductor layers.

In an embodiment, the plurality of sacrificial layers are removed using a first etching chemical, and the etching process is performed using a second etching chemical different from the first etching chemical. In an embodiment, the plurality of semiconductor layers are silicon layers, the plurality of sacrificial layers comprise germanium, and wherein an intermixing layer of silicon and germanium remain is etched by the etching process. In an embodiment, the etching process is performed using an etching chemical that has a higher germanium etching rate than a silicon etching rate.

In an embodiment, the plurality of sacrificial layers are removed through a dry etching process, and the etching process is performed through a wet etching process. In an embodiment, the etching process is performed using a mixture of NH₄OH, H₂O₂, and H₂O. In an embodiment, the method further comprises, after the etching process, performing a cleaning process.

In an embodiment, the cleaning process is performed through a dry etching process. In an embodiment, a semiconductor layer in the plurality of semiconductor layers comprises a first portion forming a lightly doped source/drain region, and a second portion contacting the gate stack, and wherein the first portion has a first height greater than a second height of the second portion. In an embodiment, the etching process is performed at an elevated temperature higher than a room temperature.

In accordance with some embodiments of the present disclosure, a device comprises dielectric isolation regions; a protruding structure higher than the dielectric isolation regions, the protruding structure comprising a plurality of semiconductor nanostructures, wherein upper ones of the plurality of semiconductor nanostructures overlap respective lower ones of the plurality of semiconductor nanostructures; a gate spacer on a first portion of the protruding structure, wherein the plurality of semiconductor nanostructures comprise first parts overlapped by the gate spacer, and the first parts have first heights; and a gate stack comprising a top portion over the protruding structure; and lower portions between second parts of the plurality of semiconductor nanostructures, wherein the second parts of the plurality of semiconductor nanostructures have second heights smaller than the first heights.

In an embodiment, one of the lower portions of the gate stack extends into the plurality of semiconductor nanostructures for recessing depths in a range between about 1 nm and about 6 nm. In an embodiment, the second parts comprise transition portions joined to the first parts, and wherein heights of the transition portions reduce gradually. In an embodiment, the plurality of semiconductor nanostructures comprise a topmost semiconductor nanostructure, and the gate stack extends into the topmost semiconductor nanostructure from top for a first recessing depth, and extends into the topmost semiconductor nanostructure from bottom for a second recessing depth, and the second recessing depth is greater than the first recessing depth. In an embodiment, a ratio of the first recessing depth to the second recessing depth is smaller than about 2/3. In an embodiment, the gate stack comprises an undercut portion overlapped by an edge portion of the gate spacer.

In accordance with some embodiments of the present disclosure, a device comprises a nanostructure transistor comprising a semiconductor nanostructure; a gate stack, wherein the gate stack encircles the semiconductor nanostructure, and the gate stack comprises an upper portion over and contacting the semiconductor nanostructure; and a lower portion under and contacting the semiconductor nanostructure, wherein the upper portion and the lower portion comprise a first part and a second part, respectively, in the semiconductor nanostructure; and a source/drain region aside of and contacting the semiconductor nanostructure.

In an embodiment, the first part extends into the semiconductor nanostructure for a first recessing depth, and the second part extends into the semiconductor nanostructure for a second recessing depth equal to the first recessing depth. In an embodiment, the first part extends into the semiconductor nanostructure for a first recessing depth, and the second part extends into the semiconductor nanostructure for a second recessing depth greater than the first recessing depth.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a multilayer stack comprising a plurality of semiconductor layers and a plurality of sacrificial layers located alternatingly;
forming a dummy gate stack on the multilayer stack;
etching the multilayer stack to form a trench;
epitaxially growing a semiconductor region in the trench to form a source/drain region;
removing the plurality of sacrificial layers from the multilayer stack;
after the sacrificial layers are removed, performing an etching process; and
after the etching process, forming a gate stack around the plurality of semiconductor layers, wherein the plurality of sacrificial layers are removed using a first etching chemical, and the etching process is performed using a second etching chemical different from the first etching chemical, and wherein the plurality of semiconductor layers are silicon layers, the plurality of sacrificial layers comprise germanium, and wherein an intermixing layer of silicon and germanium remain is etched by the etching process.
